(19) United States
(12) Patent Application Publication
(10) Pub. No.: US 2004/0140814 A1
(43) Pub. Date: Jul. 22, 2004

(54) Level meter

(76) Inventors: Achim Bletz, Clerieux (FR); Ralf Quattlander, Villingen-Schwenningen (FR)

Correspondence Address: CESARI AND MCKENNA, LLP, 88 BLACK FALCON AVENUE, BOSTON, MA, 02210, US

(21) Appl. No.: 10/625,040

(22) Filed: Jul. 23, 2003

(30) Foreign Application Priority Data
Aug. 29, 2002 (DE) 102 40 550.6

(51) Int. Cl. G01R 27/04; G01R 27/32

(52) U.S. Cl. 324/644

(57) ABSTRACT

A level meter that employs the radar principle for measuring the fill level of a medium in a container, includes a signal generator for generating and transmitting an electromagnetic signal, an electrical conductor assembly for feeding the electromagnetic signal emanating from the signal generator into the container and returning the portion of the electromagnetic signal reflected by the medium in the container, and an evaluation electronics unit that receives the portion of the electromagnetic signal reflected by the medium in the container and determines its transit or run time and thus the fill level of the medium in the container. A transducer, differentiated from the conductor assembly, is provided for measuring an additional physical variable. This enhances the functional capabilities of the level meter.

### BACKGROUND OF THE INVENTION

1. Field of the Invention

This invention relates to a level meter employing the radar concept in measuring the fill level of a medium in a container and incorporating a signal generator for generating and transmitting an electromagnetic signal, an electrical conductor assembly for conducting the electromagnetic signal emanating from the signal generator into the container and returning the portion of the electromagnetic signal that has been reflected by the medium in the container, as well as to an evaluation electronics unit that receives the portion of the electromagnetic signal reflected by the medium in the container and determines its runtime and thus the fill level of the medium in the container.

The measuring function of a level meter employing the radar concept is based on the principle of time domain reflectometry (TDR) that has been used in cable and wire testing and resembles the way conventional radar systems work. For example, in that type of TDR level meter, a short electrical pulse is transmitted via an essentially straight electrical conductor into a container that is holding a medium such as a liquid, a powder or a granulated material whose fill level is to be determined. The electrical conductor assembly, in the form of a single or dual conductor unit, is typically designed to extend into the medium. A dual-unit conductor assembly may consist for instance of two parallel conductors or of a coaxial conductor unit.

An electrical pulse fed into an electrical conductor assembly in a twin-conductor configuration travels essentially “between” the two conductors and into the container where it is at least partly reflected off the surface of the medium and the reflected portion of the short electrical pulse is received by the evaluation electronics. The reflected portion of the short electrical pulse is a function of the relative permittivity of the medium and increases commensurately with the latter. The runtime of the signal is proportional to the distance between the signal generator or the evaluation electronics and the surface of the medium in the container. The measuring accuracy of the TDR level meter is not affected by changing ambient conditions such as a rising or declining ambient pressure or temperature. Moreover, the runtime of the signal is unaffected by the relative permittivity of the medium whose fill level is to be measured.

2. Description of the Prior Art

A level meter as referred to above is described for instance in DE 100 37 715 A1. The level meter described in that publication includes a conductor assembly that extends into the container and, at the upper end of the container, into a device identified as a sensor and designed to permit level measurements by at least two mutually different measuring techniques. To that effect the sensor can function in at least two mutually different operating modes, one performing level measurements by the radar principle, the other determining the fill level by a capacitance measurement. If both measuring techniques are used either in alternating or simultaneous fashion, a plausibility check can be made in that, whenever the difference between the fill-level readings obtained by these techniques exceeds a predefined tolerance range, a corresponding alarm is triggered.

### SUMMARY OF THE INVENTION

Against the background of the prior art described above, it is the objective of this invention to introduce a level meter with expanded functional capabilities.

For a level meter of the type described above this objective is achieved by means of a transducer that is isolated from the conductor assembly and serves to measure an additional physical variable.

In principle, the conductor assembly itself can serve as a transducer by means of which an additional physical parameter can be measured, for instance by capacitance measurements. This invention, however, provides for an additional transducer by means of which, for instance, temperature, pressure or conductivity measurements are possible. In other words, with the level meter according to this invention an additional functional capability is available to the user. Without the need for an added, separate measuring instrument, the level meter according to this invention already provides at least one more measured quantity. According to a preferred embodiment of the invention, the output of the data relating to the additional physical parameter measured by the level meter takes place via a second data transfer interface. Of course, the invention is not limited to providing only one additional measured quantity. It is possible to measure and output two or more additional variables by installing two or more transducers.

The transducer can be positioned in various ways. In a preferred embodiment of the invention, however, the transducer is attached to the conductor assembly. In a particularly preferred implementation of the invention, the transducer can be detached from the conductor assembly.

As stated further above, the conductor assembly may be configured as a single- or twin-conductor unit. If the conductor assembly is a single-conductor unit, especially in the form of a tubular element or of a cable, a preferred embodiment of the invention provides for an inner conductor insulated from and extending through the single conductor unit and leading to the transducer. Particular preference is given to a single conductor unit that serves as a lead to the transducer, thus permitting the single conductor to transfer power and/or data from/to the transducer, with the electromagnetic signal emanating from the signal generator capacitively being fed into the single conductor unit. This makes it possible to arrive at a “single-wire conductor” by additionally connecting it to a reference potential such as instrument ground. In that context, a preferred implementation of the invention provides for the insulated inner conductor of the single conductor unit, leading from the single conductor within the single-conductor unit to the transducer, to serve as the connector to the reference potential and preferably to ground.

If the conductor assembly is a twin-conductor unit, either in a parallel or coaxial configuration, a preferred embodiment of the invention provides for one of the conductors to be in the form of a lead i.e. feed line to the transducer, permitting power and/or data transfer to/from the transducer by way of that feed line. The electromagnetic signal emanating from the signal generator can be fed into the conductor that serves as the lead to the transducer. In this case as well, a “single-wire feed line” to the transducer can be implemented by connecting the transducer to a reference potential such as instrument ground. To that effect, according to a preferred embodiment of the invention, the conductor other than the one serving as a lead to the transducer is used for the reference potential connection, preferably as an instrument ground connection, for the transducer. If a coaxial cable is used, that would primarily be the outer conductor.

Specifically, if the conductor assembly is a flexible cable, the end section of that cable is generally provided with a weight so as to ensure as straight as possible an extension of the conductor assembly within the container. According to a preferred implementation of the invention, the transducer would be situated on or in such a weight. Where practical, the transducer, perhaps in combination with its housing, can serve as that weight or supplement it, thus simplifying the overall design of the level meter.

The transducer additionally incorporated according to the invention may give a user of the invention level meter merely complementary information on certain physical variables such as the temperature of the medium in the container. However, according to a preferred, enhanced embodiment of the invention, an additional fill-level analysis system is provided to which the data of the additional physical variable measured by the transducer can be fed and which can serve to perform an alternative fill-level calculation on the basis of the said additionally measured physical variable. This is possible, for instance, when the additional transducer is a pressure transducer which, if at all possible, is positioned at the end of the conductor assembly near the bottom of the container, permitting an alternative level measurement based on the pressure of the medium bearing down on the pressure transducer.

In a preferred embodiment of the invention, a level meter equipped with such an additional fill-level measuring device is preferably provided with a test system that can receive fill-level measurement data acquired via the radar concept as well as the complementary fill-level data reflecting the said additional physical variable and which can compare the two fill-level values to test the reliability of the measurements obtained by the radar method. In the event of a discrepancy between the two fill-level values that exceeds a predefined reference value, an error message can be generated for the user of the level meter, alerting him to the possibility of a malfunction of the level meter and the need for an investigation of the problem.

There are numerous specific ways in which the level meter per this invention can be configured and further enhanced. In this connection, attention is invited to the dependent claims, to the following detailed description of preferred embodiments of the invention and to the corresponding drawings.

### BRIEF DESCRIPTION OF THE DRAWINGS

In the drawings:

FIG. 1 is a diagrammatic illustration showing the configuration of a level meter according to a first preferred embodiment of the invention;

FIG. 2a is a diagrammatic illustration showing the configuration of a level meter according to a second preferred embodiment of the invention;

FIG. 2b is a sectional view on a larger scale taken along line 2b-2b of FIG. 2a;

FIG. 3a is a diagrammatic illustration showing the configuration of a level meter according to a third preferred embodiment of the invention;

FIG. 3b is a sectional view of a larger scale taken along line 3b-3b of FIG. 3a;

FIG. 4 is a diagrammatic illustration showing the configuration of a level meter according to a fourth preferred embodiment of the invention;

FIG. 5 is a diagrammatic illustration showing the configuration of a level meter according to a fifth preferred embodiment of the invention, and

FIG. 6 is a diagrammatic illustration showing the configuration of a level meter according to a sixth preferred embodiment of the invention.

### DESCRIPTION OF THE PREFERED EMBODIMENTS

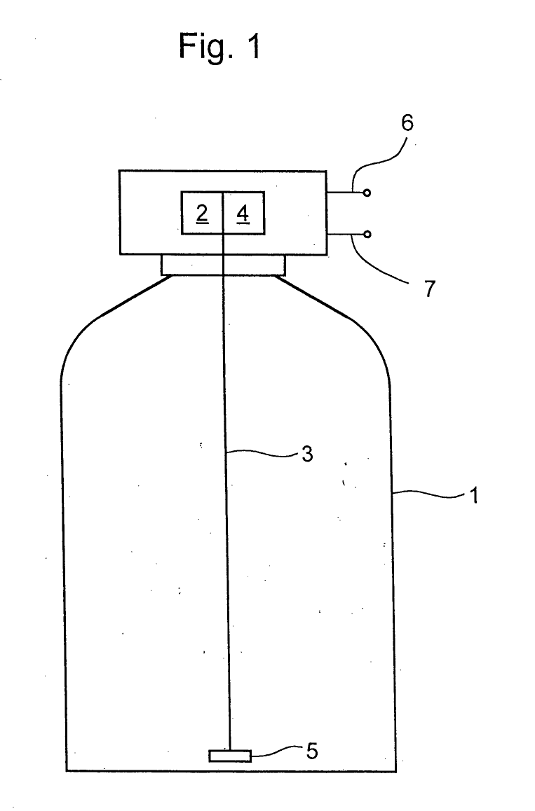

FIG. 1 shows a level meter reflecting a first preferred embodiment of the invention. The level meter is used on a container 1 that accepts a medium, not illustrated. The level meter includes a signal generator 2 capable of generating an electromagnetic signal, in this case a short microwave pulse. That electromagnetic signal is fed into an electrical conductor assembly 3 that extends almost to the bottom of the container 1. The electromagnetic signal travels along the conductor assembly 3 and is at least partly reflected back by the surface of the medium in the container 1. The reflected portion of the electromagnetic signal then travels via the electrical conductor assembly 3 to an electronic evaluation unit 4 that is capable of determining the runtime of the electromagnetic signal from the signal generator 2 to the surface of the medium and back to the evaluation electronics 4, thus permitting the determination of the fill level of the medium in the container 1. Attached to the bottom end of the conductor assembly 3 is a transducer 5 that serves to measure the temperature. The level meter according to the first preferred embodiment of the invention thus provides two measurements, one representing the fill level of the medium in the container with output via a first data interface 6, the other representing the temperature determined by the transducer 5 with output via the second data interface 7.

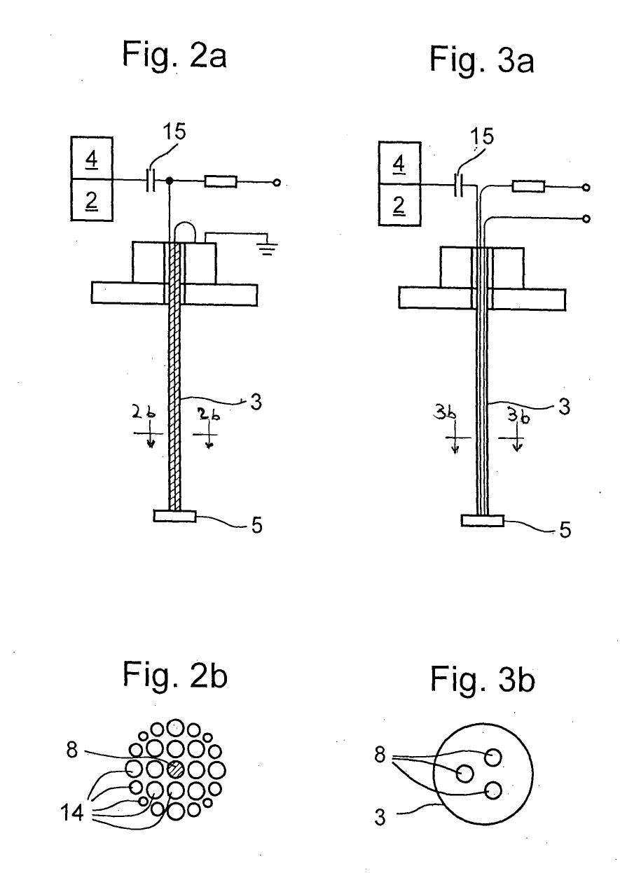

FIGS. 2a and 2b show a level meter according to a second preferred embodiment of the invention. The conductor assembly 3 of this level meter is a single conductor unit in the form of a cable composed of multiple wires 14. Extending essentially in the center of the cable and thus surrounded by the wires 14 is an inner conductor 8 that connects to the transducer 5 and is insulated from the wires 14 of the cable. In this second preferred embodiment of the level meter according to the invention, the cable serves as a lead to the transducer 5, thus permitting the cable to transfer power and/or data to/from the transducer 5. To that effect, the electromagnetic signal emanating from the signal generator 2 can be capacitively fed into the conductor cable by way of a capacitor 15. A “single-wire lead” to the transducer 5 is created in that the inner core conductor 8 serves as the ground wire connecting to the transducer 5, as schematically indicated by shading in FIG. 2b.

FIGS. 3a and 3b show a level meter according to a third preferred invention embodiment. In this level meter, the conductor assembly 3 is in the form of a conductor tube. This conductor tube can accommodate multiple inner conductors 8 which, as in the level meter according to the second preferred embodiment of the invention, are insulated against the outer conductor assembly 3. In the third preferred embodiment of the invention, the electromagnetic signal emanating from the signal generator 2 can again be fed into the conductor assembly 3, i.e. the conductor tube, via a capacitor 15. However, since the conductor tube can accommodate multiple inner conductors 8, this system is not limited to a “single-wire lead” to the transducer 5. Instead, it is possible to connect multiple transducers 5.

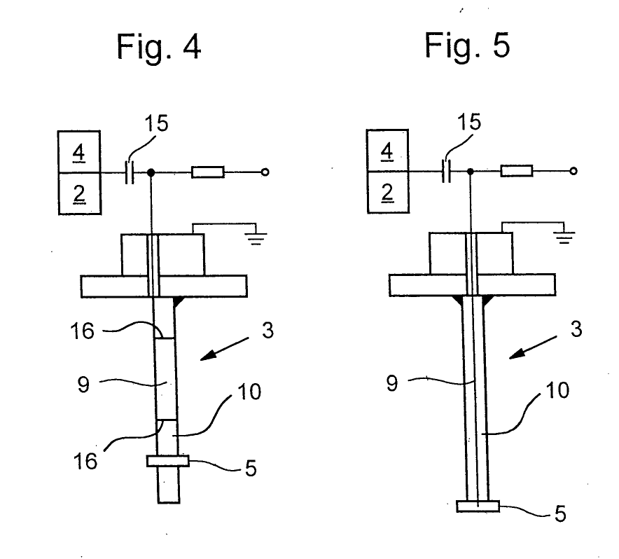

FIG. 4 shows a level meter according to a fourth preferred embodiment of the invention. In the case of this level meter, the conductor assembly 3 is in the form of a twin conductor unit with conductors 9 and 10. Provided between these conductors 9, 10 are spacers 16, while a transducer 5 is positioned slightly above the bottom end of the conductor assembly 3. In the level meter according to the fourth preferred embodiment of the invention, the conductor 9 serves as the lead to the transducer 5 so that the data and/or power transfer from/to the transducer 5 is possible via that conductor 9. And, much in the same way as described above, the electromagnetic signal emanating from the signal generator 2 can be capacitively fed into the conductor 9 via a capacitor 15. For a “single-wire lead” to the transducer 5, the other conductor 10 of the twin-conductor unit serves as the ground wire as schematically illustrated in FIG. 4.

FIG. 5 shows a level meter according to a fifth preferred embodiment of the invention. The conductor assembly 3 in this level meter is a coaxial conductor unit of which one conductor, 9, that being the inner conductor, constitutes the lead to the transducer 5. Here again, the electromagnetic signal generated by the signal generator 2 can be fed into the conductor assembly 5 via a capacitor 15. The conductor 10, that being the outer conductor of the coaxial unit, serves to provide the “single-wire lead” ground connection to the transducer 5.

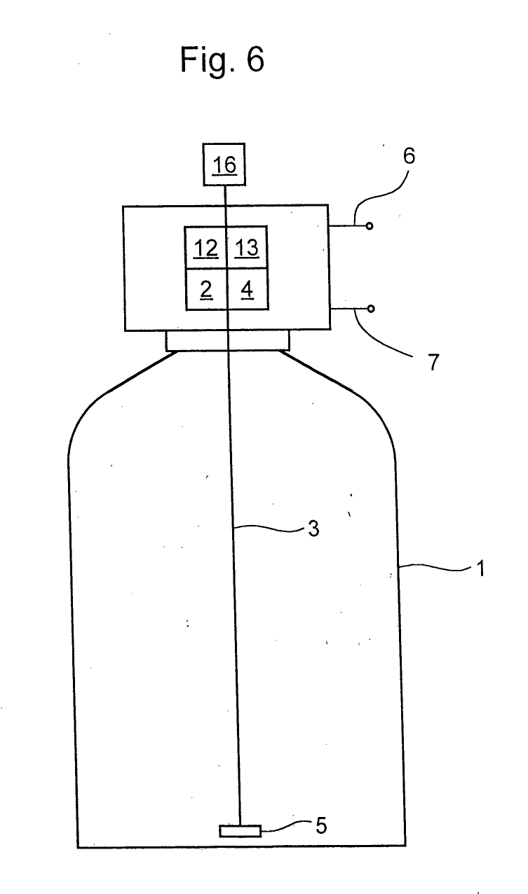

Finally, FIG. 6 shows a level meter according to a sixth preferred embodiment of the invention. This level meter additionally encompasses a fill-level analyzer 12, a test unit 13 and an output device 16.

The fill-level analyzer 12 here additionally provided, in this case a pressure transducer, can receive the data captured by the transducer 5 and representing the added physical parameter, that being the pressure prevailing at the location of the transducer 5 as a function of the medium in the container 1. Since that pressure is, as well, indicative of the level of the medium in the container 1, the fill-level analyzer 12 can provide an alternative fill-level determination.

The fill-level value measured by this alternative determination based on the pressure detected by the transducer 5 is then fed to the test unit 13. This test unit 13 also receives the fill-level value measured by the evaluation electronics on the basis of the signal transit or run time. The test unit 13 can thus compare these two fill-level values for verification of the fill-level reading obtained by the runtime method. If the delta between the two fill-level values measured by different methods exceeds a predefined reference setpoint, the output device 16 in the level meter according to the sixth preferred embodiment of the invention will generate a warning signal alerting the user to the need for checking the level meter.

What is claimed is:

1. In a level meter employing the radar principle for measuring the fill-level of a medium in a container, with a signal generator for generating and transmitting an electromagnetic signal, an electrical conductor assembly for feeding the electromagnetic signal emanating from the signal generator into the container and returning the portion of the electromagnetic signal reflected by the medium in the container, and an electronic evaluation unit that serves to receive the portion of the electromagnetic signal reflected by the medium in the container and to determine the run time of said signal and thus the fill level of the medium in the container the improvement wherein, differentiated from the conductor assembly, a transducer is provided for the purpose of measuring another physical variable.

2. The level meter as in claim 1, wherein the transducer is provided for temperature, pressure or conductivity measurements.

3. The level meter as in claim 1 or 2, and further including a data transfer interface for the output of the additional physical variable detected by the transducer.

4. The level meter as in claim 1 or 2, wherein the transducer is mounted on the conductor assembly preferably in detachable fashion.

5. The level meter as in claim 1 or 2, wherein the conductor assembly is in the form of a single-conductor unit, preferably a conductor tube or conductor cable, and an insulated inner conductor leading to the transducer extends within the single-conductor unit.

6. The level meter as in claim 5, wherein the single-conductor unit is in the form of a feed line leading to the transducer, making possible a data and/or power transfer via said single-conductor unit from or to the transducer, and the electromagnetic signal emanating from the signal generator can be capacitively coupled into the single-conductor unit.

7. The level meter as in claim 5, wherein the inner conductor, insulated from and extending within the single-conductor unit, leads to the transducer and serves as a reference-potential connection and preferably as an instrument-ground connection.

8. The level meter as in claim 1 or 2, wherein the conductor assembly is configured as a twin-conductor unit with two conductors; preferably as a parallel or a coaxial line, one of the conductors is in the form of a feed line leading to the transducer so that by way of the conductor serving as the feed line to the transducer a data and/or power transfer is possible from or to the transducer, and that the electromagnetic signal generated by the signal generator can be coupled into the conductor serving as the feed line to the transducer.

9. The level meter as in claim 8, wherein, differentiated from the conductor serving as the feed line to the transducer, the conductor serves as the reference-potential connection and preferably as the instrument-ground connection.

10. The level meter as in claim 1 or 2, and further including a weight in the end region of the conductor assembly, said transducer being positioned on or in said weight.

11. The level meter as in claim 1 or 2, and further including an additional fill-level analyzer which the additional physical variable detected by the transducer can be fed, and wherein, on the basis of the additionally detected physical variable, an alternative fill-level determination can be made.

12. The level meter as in claim 11, and further including a test unit which can receive both the fill-level information determined by the radar-type measurement and the fill-level information determined by the alternative fill-level measurement based on the additional physical variable and by means of which the two fill-level values can be compared for testing the reliability of the radar-type fill-level measurement.
